(19) United States
(12) Patent Application Publication
(10) Pub. No.: US 2010/0140719 A1
(43) Pub. Date: Jun. 10, 2010

(54) SEMICONDUCTOR DEVICE AND MANUFACTURING METHOD THEREOF

(76) Inventors: Hiroyuki YAMASAKI, Yokohama-shi (JP); Kenji Kojima, Yokohama-shi (JP); Hiroshi Naruse, Yokohama-shi (JP); Hideaki Harakawa, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/563,247

(22) Filed: Sep. 21, 2009

(30) Foreign Application Priority Data
Dec. 4, 2008 (JP) 2008-309879

(51) Int. Cl. H01L 27/06; H01L 21/28

(52) U.S. Cl. 257/379; 438/382; 257/E27.016; 257/E21.158

(57) ABSTRACT

A semiconductor device includes a substrate which includes an element region and an isolation region, a transistor portion which includes a gate insulating film formed on the element region, and a gate electrode having a metal film formed on the gate insulating film and a first semiconductor film formed on the metal film, and a resistance element portion which includes a second semiconductor film formed above the substrate and formed of the same material as that of the first semiconductor film, and a cavity formed between the substrate and the second semiconductor film.

### CROSS-REFERENCE TO RELATED APPLICATIONS

This application is based upon and claims the benefit of priority from prior Japanese Patent Application No. 2008-309879, filed Dec. 4, 2008, the entire contents of which are incorporated herein by reference.

### BACKGROUND OF THE INVENTION

1. Field of the Invention

The present invention relates to a semiconductor device and a manufacturing method thereof.

2. Description of the Related Art

To achieve a high speed of an MIS transistor, a metal gate structure in which a metal is used for at least the lowermost layer of a gate electrode has been suggested (see JP-A 2000-252371 (KOKAI)). Using the metal gate structure enables greatly reducing a resistance of the gate electrode.

However, when a metal film that is used to form the metal gate structure is also utilized for a resistance element, since a resistance of the metal film is too low, forming the resistance element having an appropriate resistance value is difficult. That is, to obtain an appropriate resistance value, the resistance element must be elongated, and an area of a region in which the resistance element is formed is thereby increased. Further, there is also a problem that a resistance change with respect to a temperature of the metal film is large and a resistance value greatly fluctuates due to a change in temperature.

As explained above, in a conventional example, obtaining an appropriate resistance element is difficult in a semiconductor device including an MIS transistor having a metal gate structure.

### BRIEF SUMMARY OF THE INVENTION

A first aspect of the present invention, there is provided a semiconductor device comprising: a substrate which includes an element region and an isolation region; a transistor portion which includes a gate insulating film formed on the element region, and a gate electrode having a metal film formed on the gate insulating film and a first semiconductor film formed on the metal film; and a resistance element portion which includes a second semiconductor film formed above the substrate and formed of the same material as that of the first semiconductor film, and a cavity formed between the substrate and the second semiconductor film.

A second aspect of the present invention, there is provided a manufacturing method of a semiconductor device, comprising: forming an insulating film on a substrate including an element region and an isolation region; forming a metal film on the insulating film; forming a semiconductor film on the metal film; patterning a stack film including the insulating film, the metal film, and the semiconductor film to form a first stack structure in a transistor forming region and a second stack structure in a resistance element forming region; and removing the metal film included in the second stack structure to form a cavity between the substrate and the semiconductor film included in the second stack structure.

### BRIEF DESCRIPTION OF THE SEVERAL VIEWS OF THE DRAWING

FIGS. 1A, 1B, and 1C are cross-sectional views each showing a configuration of a semiconductor device according to an embodiment of the present invention;

FIG. 2 is a plan view mainly showing a configuration of a resistance element forming region of the semiconductor device according to the embodiment of the present invention;

FIG. 3 is a view for describing an effect of the embodiment according to the present invention;

FIGS. 4A, 4B, and 4C are cross-sectional views each showing a part of a manufacturing method of a semiconductor device according to an embodiment of the present invention;

FIGS. 5A, 5B, and 5C are cross-sectional views each showing a part of the manufacturing method of a semiconductor device according to the embodiment of the present invention;

FIGS. 6A, 6B, and 6C are cross-sectional views each showing a part of the manufacturing method of a semiconductor device according to the embodiment of the present invention;

FIGS. 7A, 7B, and 7C are cross-sectional views each showing a part of the manufacturing method of a semiconductor device according to the embodiment of the present invention;

FIGS. 8A, 8B, and 8C are cross-sectional views each showing a part of the manufacturing method of a semiconductor device according to the embodiment of the present invention;

FIGS. 9A, 9B, and 9C are cross-sectional views each showing a part of the manufacturing method of a semiconductor device according to the embodiment of the present invention;

FIGS. 10A, 10B, and 10C are cross-sectional views each showing a part of the manufacturing method of a semiconductor device according to the embodiment of the present invention;

FIGS. 11A, 11B, and 11C are cross-sectional views each showing a part of the manufacturing method of a semiconductor device according to the embodiment of the present invention;

FIG. 12 is a plan view showing a part of the manufacturing method of a semiconductor device according to the embodiment of the present invention;

FIGS. 13A, 13B, and 13C are cross-sectional views showing a part of a manufacturing method of a semiconductor device according to a comparative example of the embodiment according to the present invention;

FIGS. 14A, 14B, and 14C are cross-sectional views showing a part of the manufacturing method of a semiconductor device according to the comparative example of the embodiment according to the present invention;

FIGS. 15A, 15B, and 15C are cross-sectional views showing a part of the manufacturing method of a semiconductor device according to the comparative example of the embodiment according to the present invention; and

FIG. 16 is a cross-sectional view showing a configuration of a semiconductor device according to a modification of the embodiment of the present invention.

### DETAILED DESCRIPTION OF THE INVENTION

An embodiment according to the present invention will now be described hereinafter with reference to the accompanying drawings.

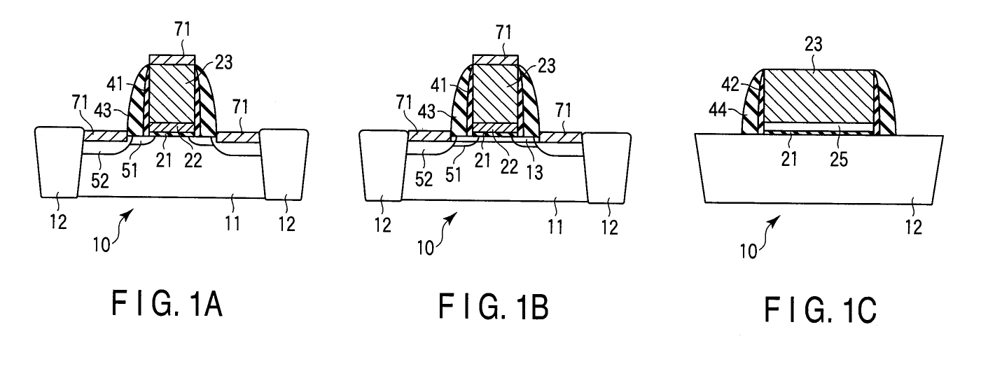

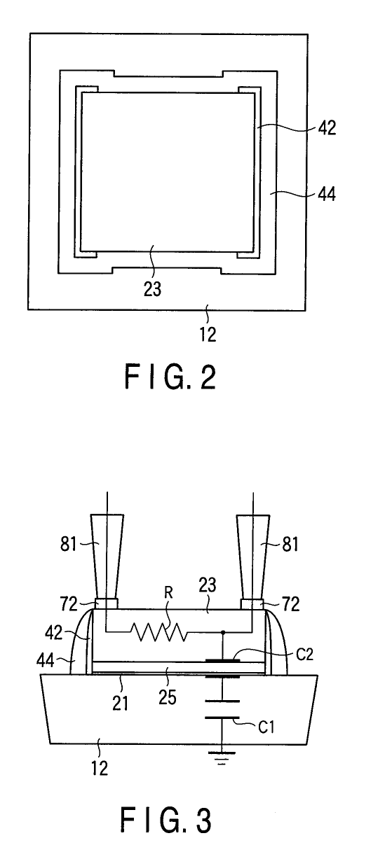

FIGS. 1A, 1B, and 1C are cross-sectional views each showing a configuration of a semiconductor device according to an embodiment of the present invention. FIG. 1A is a cross-sectional view mainly showing a configuration of an N-type MIS transistor forming region. FIG. 1B is a cross-sectional view mainly showing a configuration of a P-type MIS transistor forming region. FIG. 1C is a cross-sectional view mainly showing a configuration of a resistance element forming region. FIG. 2 is a plan view mainly showing a configuration of a resistance element forming region of the semiconductor device according to this embodiment.

As shown in FIGS. 1A, 1B, and 1C, an element region 11 and an STI (shallow trench isolation) type isolation region 12 are formed in a surface region of a substrate 10. A silicon substrate is used for a semiconductor substrate constituting the element region 11. An insulating film such as a silicon oxide film is used for the isolation region 12. Further, an SiGe layer 13 is formed in a P-type MIS transistor portion. In the P-type MIS transistor portion, since a channel is formed in the SiGe layer 13, the SiGe layer 13 is also substantially included in the element region 11.

As shown in FIGS. 1A and 1B, a gate insulating film 21 is formed on the element region 11 in each of an N-type MIS transistor portion and the P-type MIS transistor portion. A high-dielectric constant insulating film is used for the gate insulating film 21. In this embodiment, an HfSiON film is used as the high-dielectric constant insulating film. A metal film 22 is formed on the gate insulating film 21. In this embodiment, a TiN film is used for the metal film 22. It is to be noted that an La film may be formed as a work function adjusting metal film below the TiN film in the N-type MIS transistor portion, for example. A semiconductor film 23 is formed as a cap layer on the metal film 22. A silicon film containing a P-type or N-type impurity element is used for this semiconductor film 23. The metal film 22, the semiconductor film 23, and a later-explained silicide film 71 form a gate electrode having a metal gate structure. A sidewall portion 41 is formed on a side surface of a stack structure including the gate insulating film 21, the metal film 22, and the semiconductor film 23, and a sidewall portion 43 is formed on the sidewall portion 41.

An extension region 51 and a source/drain region 52 are formed on a surface of the element region 11. Furthermore, the silicide film 71 is formed on the source/drain region 52 and the semiconductor film 23.

As shown in FIG. 1C, the insulating film 21 is formed on the isolation region 12 in a resistance element portion. This insulating film 21 is formed by using the same material at the same step as those of the gate insulating film 21 of the transistor portion depicted in each of FIGS. 1A and 1B. The semiconductor film 23 is formed above the isolation region 12. This semiconductor film 23 is likewise formed by using the same material at the same step as those of the semiconductor film 23 of the transistor portion depicted in each of FIGS. 1A and 1B. Therefore, a height of the semiconductor film 23 from an upper surface of the substrate is substantially the same in the transistor portion and the resistance element portion. A cavity (air gap) 25 is formed between the isolation region 12 and the semiconductor film 23. This cavity 25 is obtained by removing a metal film deposited for the gate electrode in the transistor portion.

A sidewall portion 42 is formed on side surfaces of the insulating film 21 and the semiconductor film 23, and a sidewall portion 44 is formed on the sidewall portion 42. The sidewall portion 42 is formed by using the same material at the same step as those of the sidewall portion 41 in the transistor portion, and the sidewall portion 44 is formed by using the same material at the same step as those of the sidewall portion 43 in the transistor portion. These sidewall portions 42 and 44 are formed on opposed surfaces of the semiconductor film 23, and the semiconductor film 23 provided above the cavity 25 is supported by these sidewall portions. FIG. 2 is a plan view of FIG. 1C, and the sidewall portion 42 is not formed on the entire side surface of the semiconductor film 23 and the side surface of the semiconductor film 23 has parts on which the sidewall portion 42 is not formed as depicted in FIG. 2.

As described above, in this embodiment, although the metal film 22 is provided for the gate electrode in the transistor portion, the metal film is removed to form the cavity 25 in the resistance element portion, and the semiconductor film 23 functions as a resistor in the resistance element portion. Therefore, it is possible to obtain the resistance element that can avoid problems caused due to the metal film (a program that a resistance value of the resistance element is too low, a problem that an area in which the resistance element is formed is increased, a problem that a resistance change with respect to a temperature of the metal film is large, and others). For example, an element area can be reduced to approximately ⅕ to ⅙ of that of a resistance element using a metal electrode.

Additionally, in this embodiment, since the cavity 25 is formed below the semiconductor film 23, a capacitance between the semiconductor film 23 and the semiconductor substrate can be reduced. This point will now be described hereinafter with reference to FIG. 3. It is to be noted that reference numeral 72 denotes a silicide portion for contact and reference numeral 81 designates a contact electrode which is used to flow a current through the semiconductor film 23 in FIG. 3. Reference character R denotes a resistance component of the semiconductor film 23; C1, a capacitance component of the isolation region 12; and C2 is a capacitance component of the cavity 25.

As can be understood from FIG. 3, the capacitance component C2 of the cavity 25 is connected with the capacitance component C1 of the isolation region 12 in series in this embodiment. A relative dielectric constant (1.0) of the cavity 25 is smaller than a relative dielectric constant (approximately 3.0 to 4.0) of the isolation region (a silicon oxide film) 12. Therefore, presence of the cavity 25 between the isolation region 12 and the semiconductor film 23 enables reducing a capacitance between the semiconductor film 23 and the semiconductor substrate (a semiconductor substrate portion placed below the isolation region 12) as compared with a case where the semiconductor film 23 is directly formed on the isolation region 12. As a result, a reduction in operating speed or signal intensity caused due to the capacitance component can be suppressed, thereby obtaining the semiconductor device having excellent characteristics. For example, the capacitance can be reduced approximately 10%, and the signal intensity of the element in a high-frequency domain can be increased to be higher than a conventional value.

Further, in this embodiment, the sidewall portion 42 and the sidewall portion 44 are formed on the side surface of the semiconductor film 23, and the semiconductor film 23 is supported by these sidewall portions. Therefore, even if the cavity 25 is formed between the isolation region 12 and the semiconductor film 23, the semiconductor film 23 can be assuredly supported by these sidewall portions.

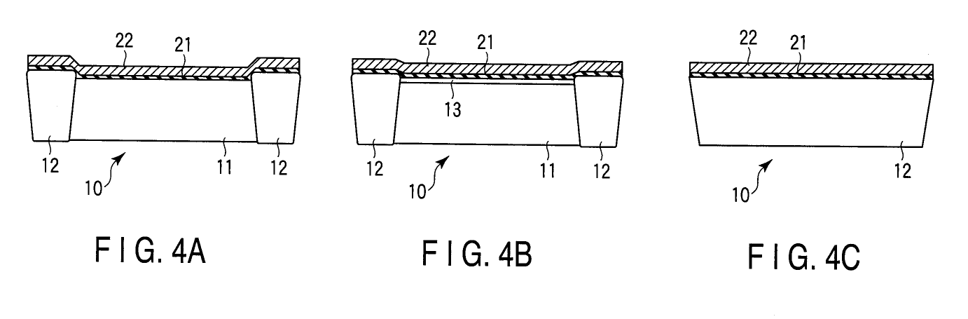

A manufacturing method of a semiconductor device according to this embodiment will now be described with reference to FIGS. 4A, 4B, 4C to 11A, 11B, and 11C. FIGS. 4A to 11A are cross-sectional views each mainly showing a configuration of the N-type MIS transistor forming region. FIGS. 4B to 11B are cross-sectional views each mainly showing a configuration of the P-type MIS transistor forming region. FIGS. 4C to 11C are cross-sectional views each mainly showing a configuration of the resistance element forming region.

First, as shown in FIGS. 4A, 4B, and 4C, the element region 11 and the isolation region 12 are formed in a surface region of the semiconductor substrate 10. A silicon substrate is used for the semiconductor substrate 10, and an insulating film such as a silicon oxide film is used for the isolation region 12. In the P-type MIS transistor forming region, the SiGe layer 13 is also formed by, e.g., an epitaxial growth method, this SiGe layer 13 is also substantially included in the element region 11.

A high-dielectric constant insulating film is deposited on the thus obtained substrate 10 to form the gate insulating film 21. As the high-dielectric constant insulating film, an HfSiON film is used. Subsequently, a TiN film is formed as the metal film 22 on the gate insulating film 21. It is to be noted that an La film may be formed as a work function adjusting metal film below the TiN film in the N-type MIS transistor forming region.

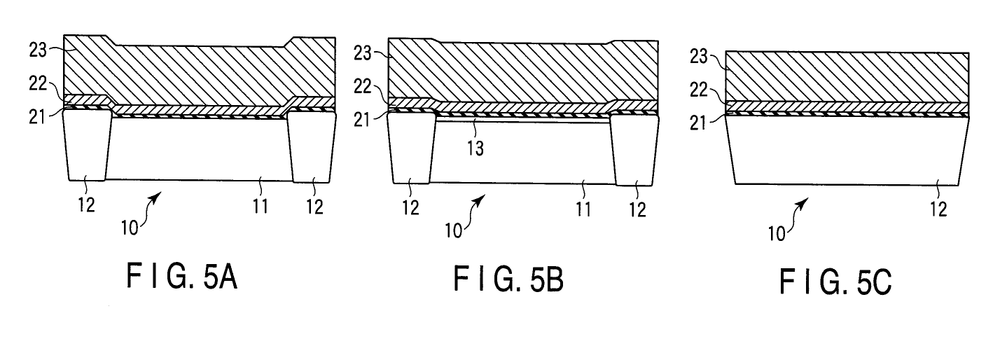

Then, as shown in FIGS. 5A, 5B, and 5C, a silicon film containing a P-type or N-type impurity element is formed as the semiconductor film 23 on the metal film 22.

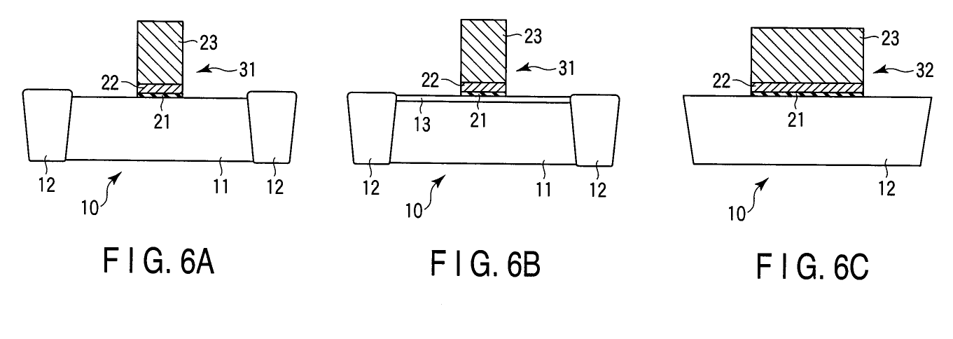

Subsequently, as shown in FIGS. 6A, 6B, and 6C, a lithography process and an etching process based on RIE (reactive ion etching) are carried out to pattern a stack film including the gate insulating film 21, the metal film 22, and the semiconductor film 23. As a result, a stack structure 31 for a gate electrode is formed in each of the N-type MIS transistor forming region and the P-type MIS transistor forming region. Furthermore, a stack structure 32 for a resistance element is formed in the resistance element forming region.

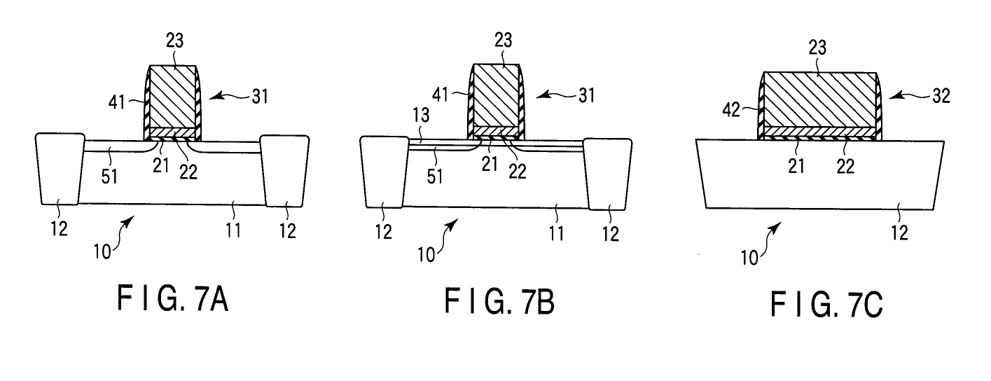

Then, as shown in FIGS. 7A, 7B, and 7C, an SiN film (a silicon nitride film) is formed as an insulating film on the entire surface, and the SiN film is subjected to anisotropic etching based on the RIE. As a result, the sidewall portion 41 is formed on a side surface of the stack structure 31, and the sidewall portion 42 is formed on a side surface of the stack structure 32. It is to be noted that a stack film including the SiN film and an NSG (non-doped silicate glass) film may be used in place of the single SiN film to form the sidewall portions 41 and 42. Subsequently, the stack structure 31 and the sidewall portion 41 are used as a mask to ion-implant an N-type impurity into the N-type MIS transistor forming region and a P-type impurity into the P-type MIS transistor forming region, respectively, thereby forming the extension region 51.

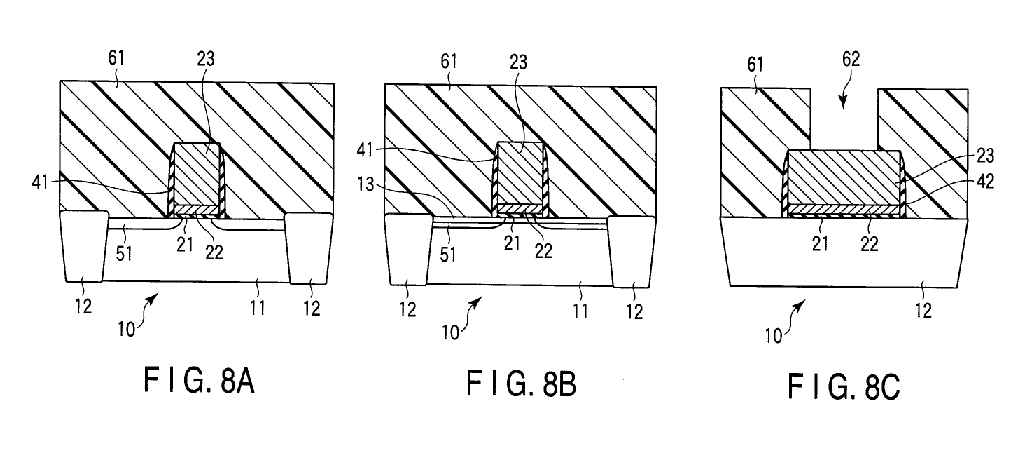

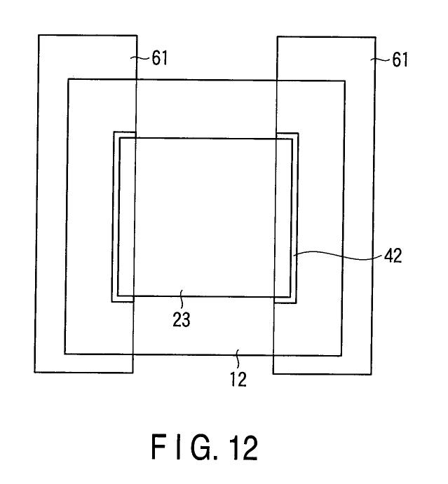

Then, as shown in FIGS. 8A, 8B, and 8C, a photoresist pattern 61 is formed. This photoresist pattern 61 covers the N-type MIS transistor forming region and the P-type MIS transistor forming region and has an opening 62 at a part of the resistance element forming region. Subsequently, the photoresist pattern 61 is used as a mask to etch the sidewall portion 42 based on dry etching or wet etching. As a result, as shown in a plan view of FIG. 12, the sidewall portion 42 in the region that is not covered with the photoresist pattern 61 is removed in the resistance element forming region. Consequently, a part of the metal film 22 alone is exposed in the resistance element forming region. On the other hand, since the metal film 22 of the MIS transistor is covered with the sidewall portion 41, it is not exposed.

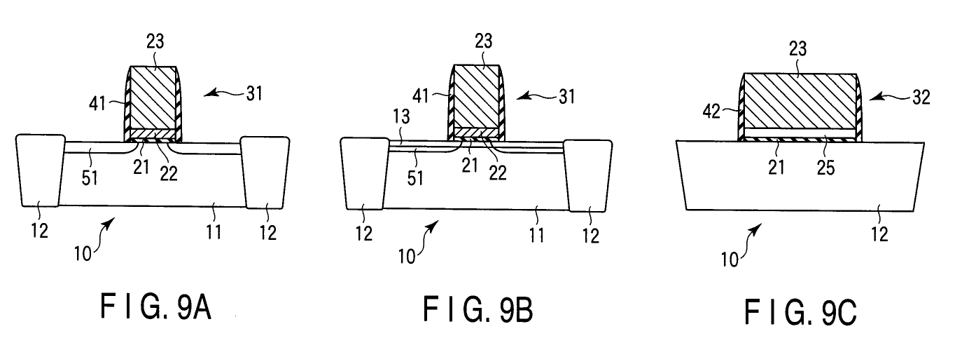

Then, as shown in FIGS. 9A, 9B, and 9C, the photoresist pattern 61 is removed by a wet process (an SH process) using a sulfuric acid and a hydrogen peroxide solution. The metal film 22 in the resistance element forming region is simultaneously removed by this wet process. That is, a wet process liquid infiltrates from the portion from which the sidewall portion 42 is removed at steps depicted in FIGS. 8A, 8B, and 8C, thereby removing the metal film 22 in the resistance element forming region. As a result, the cavity 25 is formed between the gate insulating film 21 and the semiconductor film 23. At this time, since the sidewall portion 42 is formed on the side surface of the semiconductor film 23, the sidewall portion 42 can assuredly support the semiconductor film 23 even though the cavity 25 is formed. It is to be noted that the wet process which is used to remove the photoresist pattern 61 and the wet process which is used to remove the metal film 22 are carried out at the same step, but these processes may be performed at different steps.

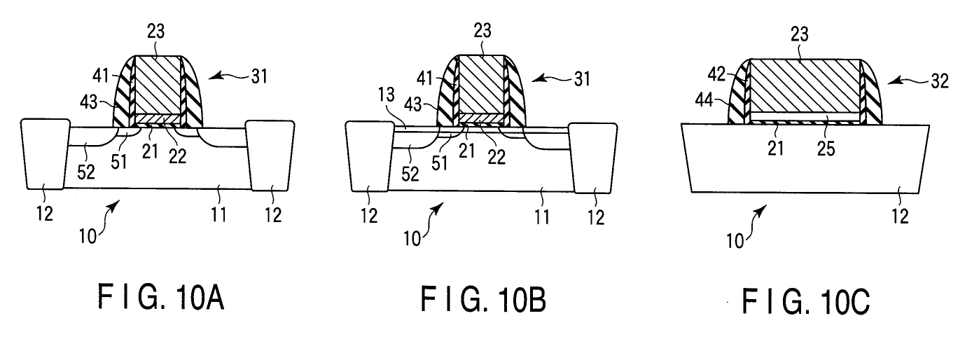

Subsequently, as shown in FIGS. 10A, 10B, and 10C, an insulating film (e.g., a silicon oxide film or a silicon nitride film) is formed on the entire surface, and this insulating film is subjected to anisotropic etching based on the RIE. As a result, the sidewall portion 43 is formed on the sidewall portion 41 of the stack structure 31, and the sidewall portion 44 is formed on the sidewall portion 42 of the stack structure 32. Then, the stack structure 31 and the sidewall portion 43 are used as a mask to ion-implant an N-type impurity into the N-type MIS transistor forming region and a P-type impurity into the P-type MIS transistor forming region, thereby forming the source/drain region 52.

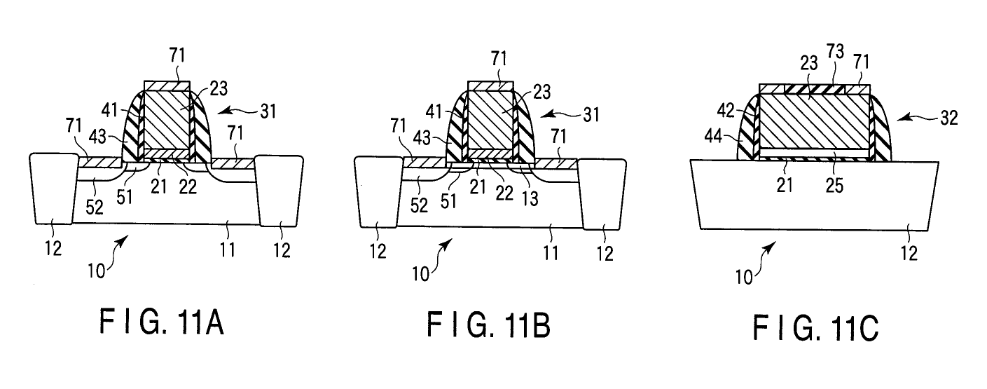

Then, as shown in FIGS. 11A, 11B, and 11C, the silicide film 71 is formed on a surface of the source/drain region 52, a surface of the semiconductor film 23 in the stack structure 31, and an electrode contact portion of the semiconductor film 23 of the resistance element portion based on a salicide (self-aligned silicide) process. It is to be noted that reference numeral 73 denotes an insulating film. Although subsequent processes will not be described in particular, formation of a silicide portion which serves as a terminal of the resistance element on the semiconductor film 23 of the resistance element portion and others are carried out.

In this manner, the semiconductor device having the transistor portion which has the metal gate structure and the resistance element portion which has the cavity portion obtained by removing the metal film is formed.

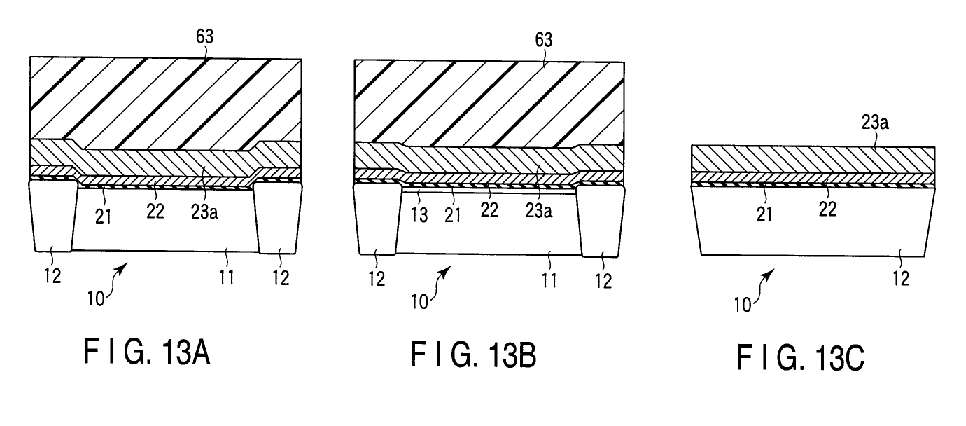

A comparative example of this embodiment will now be described with reference to FIGS. 13A, 13B, 13C to 15A, 15B, and 15C. FIGS. 13A to 15A are cross-sectional views each mainly showing a configuration of an N-type MIS transistor forming region. FIGS. 13B to 15B are cross-sectional views each mainly showing a configuration of a P-type MIS transistor forming region. FIGS. 13C to 15C are cross-sectional views each mainly showing a configuration of a resistance element forming region.

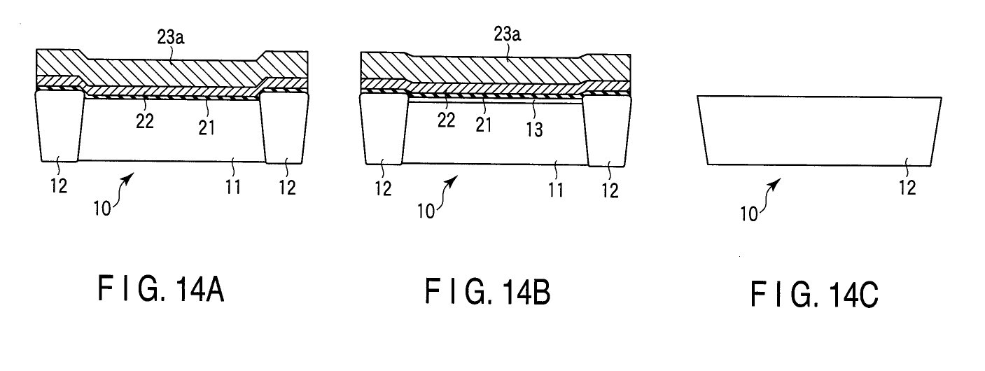

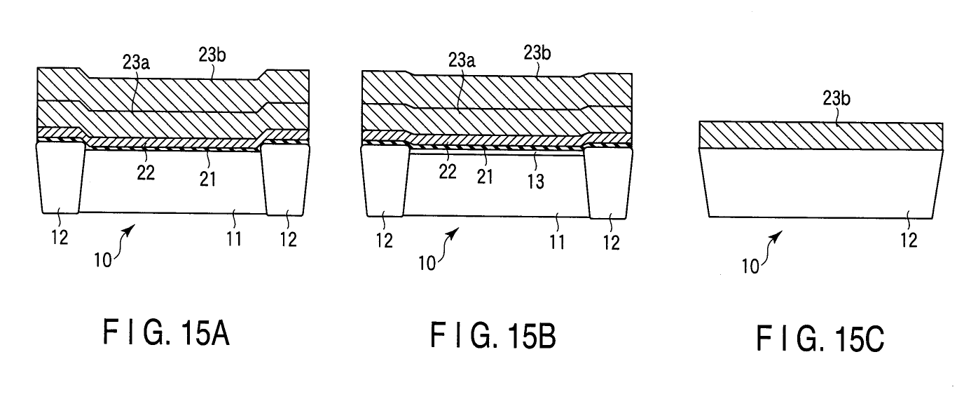

First, as shown in FIGS. 13A, 13B, and 13C, a gate insulating film 21, a metal film 22, and a semiconductor film 23a are formed on a substrate 10, and then a photoresist pattern 63 is formed on the semiconductor film 23a. This photoresist pattern 63 covers an N-type MIS transistor forming region and a P-type MIS transistor forming region but does not cover a resistance element forming region. Then, as shown in FIGS. 14A, 14B, and 14C, the photoresist pattern 63 is used as a mask to remove the gate insulating film 21, the metal film 22, and the semiconductor film 23a by etching. Subsequently, as shown in FIGS. 15A, 15B, and 15C, a semiconductor film 23b is formed on the entire surface. Although subsequent processes will not be described, the metal film 22, the semiconductor film 23a, and the semiconductor film 23b are used as a gate electrode in the transistor portion, and the semiconductor film 23b is used as a resistor in the resistance element portion.

According to the above-described comparative example, in the resistance element forming region, the gate insulating film 21, the metal film 22, and the semiconductor film 23a are formed, then these films are removed, and thereafter the semiconductor film 23b is again formed. On the other hand, in this embodiment, since the semiconductor film does not have to be removed and again formed, manufacturing processes can be reduced.

Furthermore, in the comparative example, since the semiconductor film 23b is formed on the semiconductor film 23a, an insulating film such as a native oxide film is formed at an interface between the semiconductor film 23a and the semiconductor film 23b, thereby adversely affecting transistor characteristics. On the other hand, in this embodiment, since the semiconductor film 23 is formed by the single film forming process, such a problem can be avoided, thus preventing the transistor characteristics from being degraded.

Moreover, in the comparative example, a stack structure including the metal film 22, the semiconductor film 23a, and the semiconductor film 23b are formed in the transistor portion, whereas a single-layer structure including the semiconductor film 23b is provided in the resistance element portion. Therefore, the transistor portion and the resistance element portion have different heights, thus adversely affecting the manufacturing processes. For example, when forming contact holes in an interlayer insulating film that covers the transistor and the resistance element, depths (etching amounts) of the contact holes are different from each other, and hence processing control over the contact holes is difficult. On the other hand, in this embodiment, since heights of the transistor portion and the resistance element portion can be uniformed, such a problem can be avoided, thereby enhancing the controllability of the manufacturing processes.

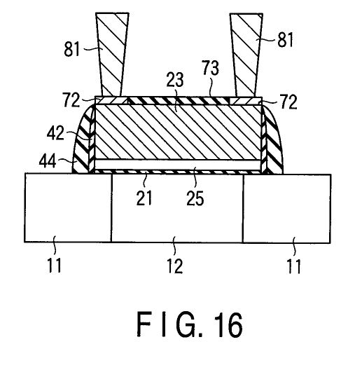

FIG. 16 is a cross-sectional view showing a configuration of a semiconductor device according to a modification of this embodiment.

In the foregoing embodiment, as shown in FIGS. 1A, 1B, and 1C, the semiconductor film 23 of the resistance element portion is formed above the isolation region 12 alone. That is, the pattern of the semiconductor film 23 is placed on the inner side of the pattern of the isolation region. In this modification, as shown in FIG. 16, a semiconductor film 23 of a resistance element portion is formed above not only an isolation region 12 but also an element region 11. That is, the pattern of the semiconductor film 23 is formed to cross a boundary between the pattern of the element region 11 and the pattern of the isolation region 12. Furthermore, a silicide portion 72 which serves as a current supply terminal is formed on a boundary region, and a contact electrode 81 is connected with the silicide portion 72. This modification will now be described hereinafter.

Since the semiconductor film of the resistance element portion functions as a resistor, it must be insulated from a semiconductor substrate. Therefore, when a cavity is not formed, the entire semiconductor film of the resistance element portion must be formed on the isolation region. Therefore, when increasing a size of the resistance element portion, a size of the isolation region must be also necessarily increased.

In this modification, as shown in FIG. 16, since a cavity 25 is formed below the semiconductor film 23, the semiconductor film 23 can be insulated from the semiconductor substrate (the element region 11) through this cavity 25. Therefore, there is no problem even though the semiconductor film 23 is partially provided above the element region 11. When the semiconductor film 23 is also formed above the element region 11 in this manner, the semiconductor film 23 having a desired size can be formed in the resistance element portion without increasing the size of the isolation region 12. However, when a region where the isolation region is not formed below the semiconductor film is increased, a capacitance between the semiconductor film and the semiconductor substrate may be possibly increased to reduce an operating speed. In this modification, the boundary between the element region 11 and the isolation region 12 is placed at a part immediately below the silicide portion 72 serving as a current supply terminal for the semiconductor film 23. Adopting this structure enables suppressing an increase in size of the isolation region and an increase in capacitance.

Although the above has described the embodiment according to the present invention, the present invention is not restricted to the foregoing embodiment.

For example, in the foregoing embodiment, as shown in FIG. 2, the semiconductor film 23 of the resistance element portion has a square pattern, but a rectangular pattern may be adopted. In this case, the sidewall portion 42 may be formed along a long side of the rectangular pattern, or it may be formed along a short side of the same.

Moreover, in the foregoing embodiment, the insulating film 21 of the resistance element portion is left without being removed, but the insulating film 21 of the resistance element portion may be removed. Therefore, in general, forming the cavity 25 between the substrate 10 and the semiconductor film 23 can suffice.

Additionally, in the foregoing embodiment, although the TiN film is used as the metal film 22, the metal film 22 other than the TiN film may be used as long as the cavity 25 can be formed based on selective etching.

Further, the resistance element portion described in the foregoing embodiment can be used for, e.g., a medium-resistance element or an eFuse.

Furthermore, the semiconductor device having the resistance element portion described in the foregoing embodiment can be applied to an analog element which is used in, e.g., a wireless LAN.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate which includes an element region and an isolation region;
a transistor portion which includes a gate insulating film formed on the element region, and a gate electrode having a metal film formed on the gate insulating film and a first semiconductor film formed on the metal film; and
a resistance element portion which includes a second semiconductor film formed above the substrate and formed of the same material as that of the first semiconductor film, and a cavity formed between the substrate and the second semiconductor film.

2. The device according to claim 1,
wherein the resistance element portion further includes a sidewall portion which is formed on the substrate and on a side surface of the second semiconductor film.

3. The device according to claim 2,
wherein the sidewall portion supports the second semiconductor film.

4. The device according to claim 2,
wherein the transistor portion further includes a sidewall portion which is formed on the substrate and on side surfaces of the gate insulating film and the gate electrode, and
the sidewall portion of the resistance element portion and the sidewall portion of the transistor portion are formed of the same material.

5. The device according to claim 1,
wherein a height of the second semiconductor film from an upper surface of the substrate is the same as a height of the first semiconductor film from the upper surface of the substrate.

6. The device according to claim 1,
wherein the second semiconductor film is formed above the isolation region.

7. The device according to claim 1,
wherein the second semiconductor film is formed to cross a boundary between the element region and the isolation region.

8. The device according to claim 1,
wherein each of the first semiconductor film and the second semiconductor film is formed of a silicon film containing an impurity element.

9. The device according to claim 1,
wherein the resistance element portion further includes an insulating film formed on the substrate and formed of the same material as that of the gate insulating film.

10. A manufacturing method of a semiconductor device, comprising:
forming an insulating film on a substrate including an element region and an isolation region;
forming a metal film on the insulating film;
forming a semiconductor film on the metal film;
patterning a stack film including the insulating film, the metal film, and the semiconductor film to form a first stack structure in a transistor forming region and a second stack structure in a resistance element forming region; and
removing the metal film included in the second stack structure to form a cavity between the substrate and the semiconductor film included in the second stack structure.

11. The method according to claim 10, further comprising:
forming a sidewall film which covers a side surface of the second stack structure; and
removing a part of the sidewall film to expose a part of the metal film included in the second stack structure,
wherein the metal film included in the second stack structure is removed by performing etching from the exposed part of the metal film.

12. The method according to claim 10,
wherein removing the metal film included in the second stack structure is performed by a wet etching process.

13. The method according to claim 10,
wherein the second stack structure is formed on the isolation region.

14. The method according to claim 10,
wherein the second stack structure is formed to cross a boundary between the element region and the isolation region.

15. The method according to claim 10,
wherein the semiconductor film is formed of a silicon film containing an impurity element.
